(19) United States
(12) Patent Application Publication
(10) Pub. No.: US 2025/0271768 A1
(43) Pub. Date: Aug. 28, 2025

(54) COMPOSITIONS FOR SELECTIVE REMOVAL OF POLYMERIC MATERIALS

(71) Applicant: ENTEGRIS, INC., Billerica, MA (US)

(72) Inventors: Hsing-Chen Wu, Hsinchu City (TW); Eri Hirahara, Shizuoka-shi (JP); Ming-Chi Liao, Taoyuan City (TW)

(21) Appl. No.: 19/060,582

(22) Filed: Feb. 21, 2025

Related U.S. Application Data
(60) Provisional application No. 63/557,159, filed on Feb. 23, 2024.

(51) Int. Cl. G03F 7/42

(52) U.S. Cl. CPC G03F 7/423

(57) ABSTRACT

Compositions are provided for selective removal of a polymeric material from a substrate. The composition comprises at least one solvent; 0.1% to 20% by weight of at least one pH adjuster based on a total weight of the wet etch composition; and 1% to 20% by weight of at least one oxidizer based on the total weight of the wet etch composition. When contacted with a non-ultraviolet treated substrate comprising a first polymeric material and a second polymeric material, the composition selectively removes the first polymeric material. Related systems and related methods are also provided.

### CROSS-REFERENCE TO RELATED APPLICATIONS

This application claims the benefit under 35 USC 119 of U.S. Provisional Patent Application No. 63/557,159, filed Feb. 23, 2024, the disclosure of which is hereby incorporated herein by reference in its entirety.

### FIELD

The present disclosure relates to compositions for selective removal of polymeric materials, and related systems and related methods.

### BACKGROUND

Conventional methods for patterning microchips do not effectively remove polymeric materials. This inability to remove the polymeric layers prevents further advancement and patterning scaling.

### SUMMARY

Some embodiments relate to a wet etch composition. In some embodiments, the wet etch composition comprises at least one solvent. In some embodiments, the wet etch composition comprises 0.1% to 20% by weight of at least one pH adjuster based on a total weight of the wet etch composition. In some embodiments, the wet etch composition comprises 1% to 20% by weight of at least one oxidizer based on the total weight of the wet etch composition. In some embodiments, when contacted with a non-ultraviolet treated substrate comprising a first polymeric material and a second polymeric material, the composition selectively removes the first polymeric material.

Some embodiments relate to a method. In some embodiments, the method comprises obtaining a non-ultraviolet treated substrate comprising a first polymeric material and a second polymeric material. In some embodiments, the method comprises obtaining a composition. In some embodiments, the composition comprises at least one solvent. In some embodiments, the composition comprises 0.1% to 20% by weight of at least one pH adjuster based on a total weight of the wet etch composition. In some embodiments, the composition comprises 1% to 20% by weight of at least one oxidizer based on the total weight of the wet etch composition. In some embodiments, the method comprises contacting the composition with the non-ultraviolet treated substrate to selectively remove the first polymeric material.

### DRAWINGS

FIG. 1 is a schematic diagram of a domain of a phase-segregated block copolymer, according to some embodiments.

FIG. 2 is a flowchart of a method for selective removal of polymer chains, according to some embodiments.

FIG. 3 is a photograph image of a substrate formed using Sample Composition 1, according to some embodiments.

FIG. 4 is a photograph image of a substrate formed using Sample Composition 2, according to some embodiments.

FIG. 5 is a photograph image of a substrate formed using Control Composition 1, according to some embodiments.

FIG. 6 is a photograph image of a substrate formed using Control Composition 2, according to some embodiments.

### DETAILED DESCRIPTION

Some embodiments relate to compositions for selective removal of polymeric materials, and related systems and related methods. The compositions disclosed herein can be employed as wet etch compositions to remove a desired polymeric material, so as to increase, for example, a critical dimension of a substrate, such as a film, in one step, without having to expose the substrate to ultraviolet irradiation, thereby realizing an efficient process that is less time-consuming, among other things, than convention processes. The compositions disclosed herein also achieve uniform removal of the desired polymeric material, over other polymeric materials, on substrates with high aspect ratio features and with complex geometries. The compositions disclosed herein can be formulated according to the particular chemistry of the substrate and thus afford wide- ranging substrate applicability, with tailored performance characteristics and enhanced polymeric material selectively.

The compositions disclosed herein may be useful for rectifying a critical dimension (CD) of patterned layers useful in semiconductor fabrication, including microchip fabrication. The compositions are useful for selective removal of a polymeric material from a substrate, such as a film, to increase a critical dimension of patterned layers. For example, through directed phase segregation of block copolymers, a layer of a polystyrene-b-polymethyl methacrylate block copolymer can be formed by coating and annealing on guiding pattern layers, so as to obtain a structural pattern with regions of a polymeric material to be removed within each polymer domain of a phase-segregated block copolymer layer. The compositions disclosed herein can be used to selectively remove the desired polymeric material, without damaging or otherwise removing other polymeric materials. It will be appreciated that, in view of the ability to formulate bespoke compositions, the compositions disclosed herein may be useful for a wide-range of substrates beyond those disclosed herein.

Unlike conventional solvent systems, in some embodiments, the compositions disclosed herein can be employed for selective removal of polymethyl methacrylate chains over polystyrene chains, without use of ultraviolet light. The selective removal of polymethyl methacrylate chains can include polymethyl methacrylate chains present in a region comprising only polymethyl methacrylate chains, as well as regions comprising both polymethyl methacrylate chains and polystyrene chains. The compositions disclosed herein can also be employed to increase or rectify a critical dimension of the layer (e.g., hole diameter of each polymer domain) or pattern, without use of ultraviolet light, relative to, for example, a conventional approach. The compositions disclosed herein can be employed to improve pattern uniformity after wet chemical development without use of ultraviolet light. The compositions disclosed herein can be employed to remove impurities. These and other benefits will become apparent to those skilled in the art in view of the disclosure herein.

Some embodiments provide compositions, including wet etch compositions, useful for selective removal of substances, such as, for example and without limitation, polymeric materials, from non-ultraviolet treated substrates. In some embodiments, a composition is provided that can selectively remove a polymeric material, by, for example, cleaving or breaking a polymer bond, without exposing the substrate to ultraviolet light. In some embodiments, the composition is useful for selectively removing a polymeric material so as to obtain well-defined pores in the substrate with uniform or substantially uniform pore sizes (e.g., an isoporous substrate). In some embodiments, the composition is useful without use of a swell controller, wherein the swell controller is configured to suppress swelling of the film.

As used herein, the terms “selectively removing,” “selective removal,” and the like, refer to removing a greater proportion of a first substance than a second substance. The second substance is generally different from the first substance. For example, in some embodiments, the first substance comprises a first polymeric material and the second substance comprises a second polymeric material, wherein the first polymeric material and the second polymeric material have different chemical constitutions.

As used herein, the term “non-ultraviolet treated substrate” refers to a substrate that has not been exposed to ultraviolet light under conditions (e.g., duration, intensity, frequency, wavelength, etc.) sufficient to cause a chemical change, a physical change, or otherwise a non-trivial change in the substrate. The term includes substrates that have been exposed to ultraviolet light (e.g., ambient conditions), provided that such exposure has not caused any chemical bonds to be cleaved, broken, or otherwise resulted in non-trivial changes. The term also includes substrates that have not had any exposure to ultraviolet light. It will be appreciated that, in some instances, at least some exposure to ultraviolet light occurs, however slight, through the normal course of handling substrates. In some embodiments, this exposure to ultraviolet light—i.e., through the normal course of handling substrates—would not result in any non-trivial changes to the substrate and thus these substrates may still be considered a non-ultraviolet light treated substrate. In some embodiments, any exposure whatsoever to ultraviolet light would be considered sufficient exposure and thus these substrates would not be considered non-ultraviolet light treated substrates.

As used herein, the term “ultraviolet treated substrate” refers to a substrate that has been exposed (e.g., subjected to, irradiated with, etc.) ultraviolet light. In some embodiments, an ultraviolet light treated substrate refers to a substrate that has been exposed to ultraviolet light under conditions sufficient to cleave a polymer backbone of a polymer present in the substrate, and/or to break a bond (e.g., chemical bonds, physical bonds, etc.) of a substance present in the substrate, and/or to depolymerize a substance present in the substrate and/or to degrade, weaken, or otherwise damage a substance present in the substrate.

As used herein, the term “cleave” refers to any form of damage or degradation to a bond. In some embodiments, the term “cleave” refers to a broken chemical bond. In some embodiments, a polymer chain that is cleaved results in broken chemical bond such that the polymer chain has a cleaved portion of the polymer chain and a non-cleaved portion of the polymer chain. In some embodiments, the polymethyl methacrylate chains present in the second region 120 have not been cleaved. In some embodiments, the polymethyl methacrylate chains present in the second region 120 have been at least partially cleaved. In some embodiments, the polymethyl methacrylate chains present in the second region 120 have been cleaved. In some embodiments, the polymethyl methacrylate chains present in the second region 120 comprise non-cleaved polymethyl methacrylate chains 140 and cleaved polymethyl methacrylate chains 150.

The composition may comprise at least one solvent.

In some embodiments, the composition comprises 5% to 99% by weight of the at least one solvent based on a total weight of the composition, or any range or subrange between 5% to 99%. In some embodiments, the composition comprises 5% to 98.9%, 5% to 95%, 5% to 85%, 5% to 80%, 5% to 75%, 5% to 70%, 5% to 65%, 5% to 60%, 5% to 55%, 5% to 50%, 5% to 45%, 5% to 40%, 5% to 35%, 5% to 30%, 5% to 25%, 5% to 20%, 5% to 15%, 5% to 10%, 10% to 90%, 15% to 90%, 20% to 90%, 30% to 90%, 35% to 90%, 40% to 90%, 45% to 90%, 50% to 90%, 55% to 90%, 60% to 90%, 65% to 90%, 70% to 90%, 75% to 90%, 80% to 90%, 85% to 90%, 45% to 65%, 45% to 60%, 45% to 55%, 45% to 50%, 50% to 65%, 55% to 65%, 60% to 65%, 15% to 30%, 20% to 30%, 25% to 30%, 15% to 25%, or 15% to 20% by weight of the at least one solvent based on a total weight of the composition. In some embodiments, the upper bounds for the at least one solvent, including any species thereof, is 98.9%. For example, in some embodiments, the composition comprises 50% to 98.9% by weight of the at least one solvent based on the total weight of the composition.

In some embodiments, the at least one solvent comprises at least one alcohol solvent. In some embodiments, the composition comprises 50% to 99% by weight of the at least one alcohol solvent based on the total weight of the composition, or any range or subrange between 50% and 99%. In some embodiments, the composition comprises 50% to 95%, 50% to 90%, 50% to 85%, 50% to 80%, 50% to 75%, 50% to 70%, 50% to 65%, 50% to 60%, 50% to 55%, 55% to 99%, 60% to 99%, 65% to 99%, 70% to 99%, 75% to 99%, 80% to 99%, 85% to 99%, 90% to 99%, or 95% to 99% by weight of the at least one alcohol solvent based on the total weight of the composition. For example, in some embodiments, the at least one alcohol solvent comprises at least one tertiary alcohol solvent.

In some embodiments, the at least one solvent comprises at least one non-alcohol solvent. In some embodiments, the composition comprises 1% to 50% by weight of the at least one non-alcohol solvent based on the total weight of the composition, or any range or subrange between 1% and 50%. In some embodiments, the composition comprises 1% to 45%, 1% to 40%, 1% to 35%, 1% to 30%, 1% to 25%, 1% to 20%, 1% to 15%, 1% to 10%, 1% to 5%, 5% to 50%, 10% to 50%, 15% to 50%, 20% to 50%, 25% to 50%, 30% to 50%, 35% to 50%, 40% to 50%, or 45% to 50% by weight of the at least one non-alcohol solvent based on the total weight of the composition.

In some embodiments, the at least one solvent comprises at least one non-alcohol solvent. In some embodiments, the composition comprises 50% to 99% by weight of the at least one non-alcohol solvent based on the total weight of the composition, or any range or subrange between 50% and 99%. In some embodiments, the composition comprises 50% to 95%, 50% to 90%, 50% to 85%, 50% to 80%, 50% to 75%, 50% to 70%, 50% to 65%, 50% to 60%, 50% to 55%, 55% to 99%, 60% to 99%, 65% to 99%, 70% to 99%, 75% to 99%, 80% to 99%, 85% to 99%, 90% to 99%, or 95% to 99% by weight of the at least one non-alcohol solvent based on the total weight of the composition.

In some embodiments, the at least one solvent comprises at least one organic solvent. In some embodiments, the composition comprises 5% to 90% by weight of the at least one organic solvent based on the total weight of the composition, or any range or subrange between 5% to 90%. In some embodiments, the composition comprises 5% to 85%, 5% to 80%, 5% to 75%, 5% to 70%, 5% to 65%, 5% to 60%, 5% to 55%, 5% to 50%, 5% to 45%, 5% to 40%, 5% to 35%, 5% to 30%, 5% to 25%, 5% to 20%, 5% to 15%, 5% to 10%, 10% to 90%, 15% to 90%, 20% to 90%, 30% to 90%, 35% to 90%, 40% to 90%, 45% to 90%, 50% to 90%, 55% to 90%, 60% to 90%, 65% to 90%, 70% to 90%, 75% to 90%, 80% to 90%, 85% to 90%, 45% to 65%, 45% to 60%, 45% to 55%, 45% to 50%, 50% to 65%, 55% to 65%, 60% to 65%, 15% to 30%, 20% to 30%, 25% to 30%, 15% to 25%, or 15% to 20% by weight of the at least one organic solvent based on a total weight of the composition.

In some embodiments, the at least one solvent comprises water. In some embodiments, the composition comprises 5% to 90% by weight of the water based on the total weight of the composition, or any range or subrange between 5% to 90%. In some embodiments, the composition comprises 5% to 85%, 5% to 80%, 5% to 75%, 5% to 70%, 5% to 65%, 5% to 60%, 5% to 55%, 5% to 50%, 5% to 45%, 5% to 40%, 5% to 35%, 5% to 30%, 5% to 25%, 5% to 20%, 5% to 15%, 5% to 10%, 10% to 90%, 15% to 90%, 20% to 90%, 30% to 90%, 35% to 90%, 40% to 90%, 45% to 90%, 50% to 90%, 55% to 90%, 60% to 90%, 65% to 90%, 70% to 90%, 75% to 90%, 80% to 90%, 85% to 90%, 45% to 65%, 45% to 60%, 45% to 55%, 45% to 50%, 50% to 65%, 55% to 65%, 60% to 65%, 15% to 30%, 20% to 30%, 25% to 30%, 15% to 25%, 10% to 95%, or 15% to 20% by weight of the water based on a total weight of the composition.

The composition may comprise at least one pH adjuster.

In some embodiments, the composition comprises 0.1% to 20% by weight of the at least one pH adjuster based on the total weight of the composition, or any range or subrange between 0.1% to 20%. In some embodiments, the composition comprises 0.1% to 19%, 0.1% to 18%, 0.1% to 17%, 0.1% to 16%, 0.1% to 15%, 0.1% to 14%, 0.1% to 13%, 0.1% to 12%, 0.1% to 11%, 0.1% to 10%, 0.1% to 9%, 0.1% to 8%, 0.1% to 7%, 0.1% to 6%, 0.1% to 5%, 0.1% to 4%, 0.1% to 3%, 0.1% to 2%, 0.1% to 1%, 0.1% to 0.9%, 0.1% to 0.8%, 0.1% to 0.7%, 0.1% to 0.6%, 0.1% to 0.5%, 0.1% to 0.4%, 0.1% to 0.3%, 0.1% to 0.2%, 0.5% to 20%, 1% to 20%, 2% to 20%, 3% to 20%, 4% to 20%, 5% to 20%, 6% to 20%, 7% to 20%, 8% to 20%, 9% to 20%, 10% to 20%, 11% to 20%, 12% to 20%, 13% to 20%, 14% to 20%, 15% to 20%, 16% to 20%, 17% to 20%, 18% to 20%, or 19% to 20% by weight of the at least one pH adjuster based on the total weight of the composition.

The composition may comprise at least one oxidizer.

In some embodiments, the composition comprises 0.1% to 20% by weight of the at least one oxidizer based on the total weight of the composition, or any range or subrange between 0.1% to 20%. In some embodiments, the composition comprises 0.1% to 19%, 0.1% to 18%, 0.1% to 17%, 0.1% to 16%, 0.1% to 15%, 0.1% to 14%, 0.1% to 13%, 0.1% to 12%, 0.1% to 11%, 0.1% to 10%, 0.1% to 9%, 0.1% to 8%, 0.1% to 7%, 0.1% to 6%, 0.1% to 5%, 0.1% to 4%, 0.1% to 3%, 0.1% to 2%, 0.1% to 1%, 0.1% to 0.9%, 0.1% to 0.8%, 0.1% to 0.7%, 0.1% to 0.6%, 0.1% to 0.5%, 0.1% to 0.4%, 0.1% to 0.3%, 0.1% to 0.2%, 0.5% to 20%, 1% to 20%, 2% to 20%, 3% to 20%, 4% to 20%, 5% to 20%, 6% to 20%, 7% to 20%, 8% to 20%, 9% to 20%, 10% to 20%, 11% to 20%, 12% to 20%, 13% to 20%, 14% to 20%, 15% to 20%, 16% to 20%, 17% to 20%, 18% to 20%, or 19% to 20% by weight of the at least one pH adjuster based on the total weight of the composition. In some embodiments, the composition comprises 1% to 9%, 2% to 8%, 3% to 7%, 4% to 6%, 2% to 7%, 2% to 6%, or 3% to 6% by weight of the at least one pH adjuster based on the total weight of the composition.

The composition may comprise at least one oxidizing agent stabilizer. In some embodiments, the composition comprises 0.1% to 10% by weight of the at least one oxidizing agent stabilizer based on the total weight of the composition, or any range or subrange between 0.0001% to 5%. In some embodiments, the composition comprises 0.0001% to 4%, 0.0001% to 3%, 0.0001% to 2%, 0.0001% to 1%, 0.0001% to 0.1%, 0.0001% to 0.01%, 0.0001% to 0.001%, 0.001% to 5%, 0.01% to 5%, 0.1% to 5%, 1% to 5%, 2% to 5%, 3% to 5%, or 4% to 5% by weight of the at least one oxidizing agent stabilizer based on the total weight of the composition.

The composition may not comprise at least one swell controller. In some embodiments, for example, the composition comprises 0% by weight of the at least one swell controller based on the total weight of the composition. In some embodiments, the composition is substantially free of the at least one swell controller. For example, in some embodiments, the composition may comprise 0.1% to 5%, 0.1% to 4%, 0.1% to 3%, 0.1% to 2%, 0.1% to 1%, or 0.1% to 0.5% by weight of the at least one swell controller based on the total weight of the composition. In some embodiments, the composition is free of the at least one swell controller. For example, in some embodiments, the composition comprises 0.1% to 0.9%, 0.1% to 0.8%, 0.1% to 0.7%, 0.1% to 0.6%, 0.1% to 0.5%, 0.1% to 0.4%, 0.1% to 0.3%, 0.1% to 0.2% by weight of the at least one swell controller based on the total weight of the composition.

In some embodiments, the composition comprises the at least one swell controller. In some embodiments, the composition comprises 1% to 25% by weight of the at least one swell controller based on the total weight of the composition, or any range or subrange between 1% to 25%. In some embodiments, the composition comprises 1% to 24%, 1% to 22%, 1% to 20%, 1% to 18%, 1% to 16%, 1% to 15%, 1% to 14%, 1% to 12%, 1% to 10%, 1% to 8%, 1% to 6%, 1% to 5%, 1% to 4%, 1% to 2%, 2% to 25%, 4% to 25%, 5% to 25%, 6% to 25%, 8% to 25%, 10% to 25%, 12% to 25%, 14% to 25%, 15% to 25%, 16% to 25%, 18% to 25%, 20% to 25%, 22% to 25%, or 24% to 25% by weight of the at least one swell controller based on the total weight of the composition.

In some embodiments, a remainder of the composition comprises the at least one solvent.

The at least one solvent may comprise one or more solvents (e.g., one (1) solvent to ten (10) solvents, or any number of solvents between one and ten). The at least one solvent may comprise one or more substances (e.g., compounds, solvents, etc.) that is compatible with an oxidative environment and/or that selectively removes a first polymeric material and/or that increases an etch rate (or removal rate) of the first polymeric material. In some embodiments, the at least one solvent comprises a first solvent and a second solvent, wherein the first solvent selectively removes a first polymeric material and is compatible in an oxidative environment, and wherein the second solvent increases an etch rate (or removal rate) of the first polymeric material relative to a control composition which does not comprise the second solvent and is compatible in an oxidative environment. Non-limiting examples of the at least one solvent include, for example and without limitation, at least one of tertiary alcohols, tert-butyl alcohol, tert-amyl alcohol, 3-ethyl-3-pentanol, 2-methyl-2-pentanol, 3-methyl-3-pentanol, 2-methyl-2-hexanol, 3-methyl-3-octanol, ketones, acetone, cyclohexanone, methyl ethyl ketone, methyl isobutyl ketone, gamma butyrolactone, delta-valerolactone, gamma-valerolactone, 6-hexanolactone, sulfolane, dimethyl sulfoxide, dimethyl sulfone, 2-pentanone, 3-pentanone, 4-heptanone, 2-butanone, acetophenone, acetylacetone, 5-nonanone, esters, methyl acetate, ethyl acetate, isopropyl acetate, n-butyl acetate, 2-ethoxyethyl acetate, benzyl benzoate, ethyl lactate, propylene glycol monomethyl ether acetate, dimethyl succinate, dimethyl malonate, dimethyl adipate, carbonates, ethylene carbonate, propylene carbonate, dimethyl carbonate, diethyl carbonate, ethyl methyl carbonate, fluoroethylene carbonate, 1,2-butylene carbonate, 2,3-butylene carbonate, or any combination thereof. In some embodiments, the at least one solvent comprises at least one of tert-butyl alcohol, deionized water, gamma butyrolactone, propylene carbonate, sulfolane, acetic acid, or any combination thereof. In some embodiments, the composition does not comprise acetic acid. In some embodiments, the composition does not comprise an acetic acid-containing compound. In some embodiments, the composition does not comprise an acetic acid derivative. In some embodiments, the composition does not comprise deionized water.

The at least one pH adjuster can comprise a substance (e.g., a compound) that modifies a pH of the composition. In some embodiments, the at least one pH adjuster adjusts a pH of the composition to a pH of 0 to 14, or any range or subrange between 0 and 14. In some embodiments, the at least one pH adjuster adjusts a pH of the composition to a pH of 0 to 14, 0 to 13, 0 to 12, 0 to 11, 0 to 10, 0 to 9, 0 to 8, 0 to 7, 0 to 6, 0 to 5, 0 to 4, 0 to 3, 0 to 2, 0 to 1, 1 to 14, 2 to 14, 3 to 14, 4 to 14, 5 to 14, 6 to 14, 7 to 14, 8 to 14, 9 to 14, 10 to 14, 11 to 14, 12 to 14, 13 to 14, 1 to 7, 1 to 6, 1 to 5, 1 to 4, 1 to 3, 1 to 2, 2 to 7, 3 to 7, 4 to 7, 5 to 7, 6 to 7, 8 to 14, 9 to 14, 10 to 14, 11 to 14, 12 to 14, 13 to 14, 8 to 13, 8 to 12, 8 to 11, 8 to 10, or 8 to 9.

In some embodiments, the at least one pH adjuster reduces a pH of the composition to a pH of 0 to 7, or any range or subrange between 0 to 7. In other embodiments, the at least one pH adjuster increases a pH of the composition to a pH of 0 to 7, or any range or subrange between 0 to 7. In some embodiments, the at least one pH adjuster improves critical diameter uniformity. In some embodiments, the at least one pH adjuster comprises an acid of varying strength, such as a strong acid. Non-limiting examples of the at least one pH adjuster include, for example and without limitation, at least one of methanesulfonic acid, sulfonic acid, benzenesulfonic acid, trifluoromethanesulfonic acid, dodecylbenzenesulphonic acid, trifluoroacetic acid, difluoroacetic acid, trichloroacetic acid, dichloroacetic acid, perfluorooctanoic acid, hydrochloric acid, hydroiodic acid, acetic acid, oxalic acid, maleic acid, glycolic acid, formic acid, phosphoric acid, choline hydroxide, tetrabutylammonium hydroxide (TBAH), tetramethylammonium hydroxide (TMAH), tetraethylammonium hydroxide (TEAH), tetrapropylammonium hydroxide (TPAH), triethylamine (TEA), or any combination thereof. In some embodiments, the at least one pH adjuster comprises at least one of methane sulfonic acid (e.g., 70% methane sulfonic acid), trifluoro acetic acid, or any combination thereof.

The at least one oxidizer can comprise a substance (e.g., a compound) that performs a function similar to the function of ultraviolet light (e.g., exposure thereto). For example, in some embodiments, the at least one oxidizer cleaves or breaks polymer bonding in the substrate. In some embodiments, the at least one oxidizer selectively cleaves or breaks polymer bonding in the substrate. In some embodiments, the at least one oxidizer comprises at least one of a metal halide compound, a metal nitrate compound, a metal peroxymonosulfate compound, a metal persulfate compound, a metal perborate compound, a metal permanganate compound, a metal hypochlorite compound, a peroxide compound, a peroxymonosulfate compound, a nitrogen-containing compound, an acid, an ammonium compound, or any combination thereof. Non-limiting examples of the at least one oxidizer include, for example and without limitation, at least one of hydrogen peroxide (H₂O₂), FeCl₃, FeF₃, Fe(NO₃)₃, Sr(NO₃)₂, CoF₃, MnF₃, oxone, (2KHSO₅·KHSO₄·K₂SO₄), ammonium peroxomonosulfate, ammonium chlorate (NH₄ClO₃), ammonium chlorite (NH₄ClO₂), ammonium iodate (NH₄IO₃), ammonium nitrate (NH₄NO₃), ammonium perborate (NH₄BO₃), ammonium perchlorate (NH₄ClO₄), ammonium periodate (NH₄IO₄), ammonium persulfate ((NH₄)₂S₂O₈), ammonium hypochlorite (NH₄ClO), ammonium tungstate ((NH₄)₁₀H₂(W₂O₇)), sodium persulfate (Na₂S₂O₈), sodium hypochlorite (NaClO), sodium perborate, potassium iodate (KlO₃), potassium permanganate (KMnO₄), potassium persulfate (K₂S₂O₈), potassium hypochlorite (KClO), tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)IO₄), tetramethylammonium persulfate ((N(CH₃)₄)S₂O₈), tetrabutylammonium peroxomonosulfate, peroxomonosulfuric acid, urea hydrogen peroxide ((CO(NH₂)₂)H₂O₂), peracetic acid (CH₃(CO)OOH), t-butyl hydroperoxide, nitrobenzenesulfonate, 1,4-benzoquinone, toluquinone, dimethyl-1,4-benzoquinone, chloranil, alloxan, periodic acid, and combinations thereof. Preferably, the oxidizing agent comprises hydrogen peroxide, urea-hydrogen peroxide, ammonium persulfate, periodic acid, peracetic acid, t-butyl hydroperoxide, or any combination thereof. In some embodiments, the at least one oxidizer comprises at least one of hydrogen peroxide (e.g., 31% hydrogen peroxide), isophthalic acid, or any combination thereof.

The at least one oxidizing agent stabilizer can comprise a substance (e.g., a compound) that improves performance of the oxidizer as an oxidant. In some embodiments, the at least one oxidizing agent stabilizer comprises a substance that prevents or reduces decomposition of the oxidizer. For example, decomposition of the oxidizer can diminish the oxidizer's performance as an oxidant, so the at least one oxidizing agent stabilizer can be used to improve or enhance performance of the composition. In some embodiments, the at least one oxidizing agent stabilizer comprises at least one of a chelating compound, an acid, or any combination thereof. Non-limiting examples of the at least one oxidizing agent stabilizer include, for example and without limitation, at least one of glycine, serine, proline, leucine, alanine, asparagine, aspartic acid, glutamine, valine, and lysine, nitrilotriacetic acid, iminodiacetic acid, etidronic acid, ethylenediaminetetraacetic acid (EDTA), (1,2-cyclohexylenedinitrilo)tetraacetic acid (CDTA), uric acid, tetraglyme, diethylenetriamine pentaacetic acid, propylenediamine tetraacetic acid, ethylenediamine disuccinic acid, sulfanilamide, and or any combination thereof.

The at least one swell controller can comprise a substance that improves the CD and/or LCDU. In some embodiments, the non-alcohol solvent improves CD. In some embodiments, a particular solution species may act as a solvent when present in the solution at a first concentration, and may act as a swell controller when present in the solution at a second concentration, wherein the first concentration is different from the second concentration. As one non-limiting example, a (tert)-alcohol solvent may function as a solvent at a first concentration; and the same alcohol solvent may function as a swelling controller at a second concentration, wherein the second concentration is less than the first concentration. In some embodiments, the pH adjuster comprises tetrabutylammonium hydroxide (TBAH). In some embodiments, the swell controller comprises a C₅-C₈ alcohol. In some embodiments, the swell controller comprises a linear C₁-C₂₀ alcohol. In some embodiments, the swell controller comprises a branched C₂-C₂₀ alcohol. In some embodiments, the composition does not comprise the at least one swell controller.

It was unexpectedly discovered, among other things, that the composition can be formulated, by selecting the components of the composition and by selecting the relative amounts for each of the components, according to desired performance characteristics for a given substrate. For example, it was unexpectedly discovered that a combination of the at least one oxidizer and the at least one pH adjuster may improve selective removal of a polymeric material (e.g., by minimizing removal of polymeric materials which are not to be removed) and enhance the performance of the oxidizer (e.g., amount of the polymeric material removed), while improving uniformity of the critical diameter. It was also unexpectedly discovered that a low pH range (e.g., less than 7, or less than or equal to 7) further enhances oxidizer activity, while the at least one solvent improves computability and selectivity.

In some embodiments, the composition is formulated (e.g., components of composition and relative amounts of those components are selected, adjusted, and/or modulated) to have a pH of 0 to 7, or any range or subrange between 0 and 7. In some embodiments, for example, the composition has a pH of 0 to 6, 0 to 5, 0 to 4, 0 to 3, 0 to 2, 0 to 1, 1 to 7, 2 to 7, 3 to 7, 4 to 7, 5 to 7, 6 to 7, 1 to 6, 2 to 6, 3 to 6, 4 to 6, or 5 to 6.

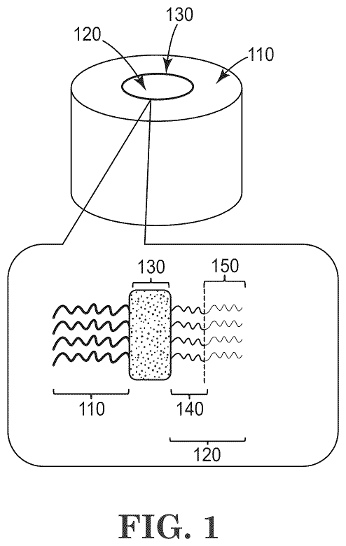

FIG. 1 is a schematic diagram of a domain 100 of a layer of a non-ultraviolet treated substrate, according to some embodiments. As shown in FIG. 1, in some embodiments, the domain 100 is present in a substrate comprising a phase-segregated block copolymer. In some embodiments, the domain 100 comprises at least one of a first region 110, a second region 120, a third region 130, or any combination thereof. In some embodiments, the first region 110 comprises a first polymeric material (e.g., polystyrene chains). In some embodiments, the second region 120 comprises a second polymeric material (e.g., polymethyl methacrylate chains). In some embodiments, the third region is located between the first region 110 and the second region 120. In some embodiments, the third region 130 comprises an intermixed region. In some embodiments, the third region 130 comprises an unsegregated portion of the first polymeric material and the second polymeric material. In some embodiments, the second region does not comprise the first polymeric material. In some embodiments, the first region does not comprise the second polymeric material.

As used herein, the term “cleave” refers to any form of damage or degradation to a bond. In some embodiments, the term “cleave” refers to a broken chemical bond. In some embodiments, a polymer chain that is cleaved results in broken chemical bond such that the polymer chain has a cleaved portion of the polymer chain and a non-cleaved portion of the polymer chain. In some embodiments, the first polymeric material is to be cleaved, whereas the second polymeric material is not to be cleaved. In some embodiments, the substrate, prior to being contacted with the composition, does not comprise pores (e.g., well-defined pores) and/or is not a porous substrate. In some embodiments, after the substrate is contacted with the composition, the substrate is a porous substrate (e.g., an isoporous substrate and/or a substrate with well-defined pores).

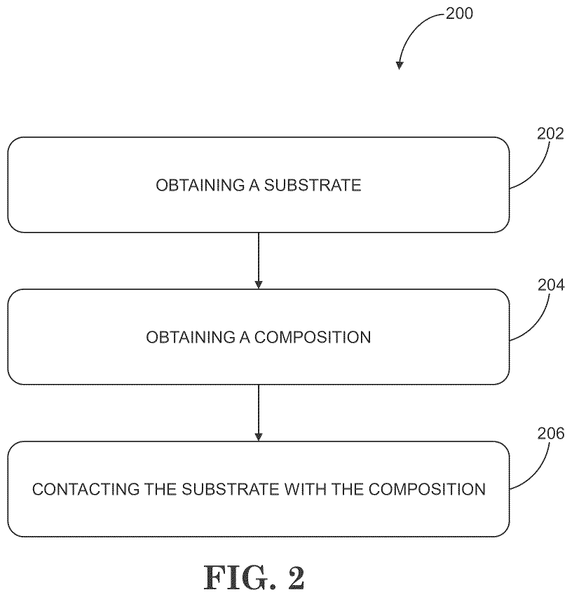

FIG. 2 is a flowchart of a method 200 for selective removal of polymer chains, according to some embodiments. As shown in FIG. 2, in some embodiments, the method 200 comprises one or more of the following steps: obtaining 202 a substrate; obtaining 204 a composition; contacting 206 the substrate with the composition (e.g., to form a porous layer or a layer having a surface morphology). In some embodiments, the method 200 does not comprise a step of exposing or irradiating a substrate with ultraviolet light.

At step 202, in some embodiments, a substrate is obtained. The substrate may comprise any substance capable of being selectively removed by the composition disclosed herein. For example, in some embodiments, the substrate comprises a non-ultraviolet treated substrate. In some embodiments, the non-ultraviolet treated substrate does not comprise a porous substrate. In some embodiments, the non-ultraviolet treated substrate does not comprise well-defined pores. In some embodiments, the non-ultraviolet treated substrate is nonporous. In some embodiments, the substrate comprises a first polymeric material and a second polymeric material. In some embodiments, the substrate comprises a non-ultraviolet treated substrate comprising a first polymeric material and a second polymeric material.

In some embodiments, the substrate comprises a layer of a block copolymer. In some embodiments, the layer of the block copolymer comprises a layer of a phase segregated block copolymer. In some embodiments, the layer of the block copolymer comprises a layer of a first polymeric material and a second polymeric material. In some embodiments, the layer of the block copolymer comprises a layer of a polystyrene-b-polymethyl methacrylate block copolymer. In some embodiments, the layer of the block copolymer comprises a plurality of polymer domains. In some embodiments, the plurality of polymer domains is formed as a result of the phase segregation of the first polymeric material and the second polymeric material. In some embodiments, the second polymeric material is different from the first polymeric material. In some embodiments, the plurality of polymer domains is formed as a result of the phase segregation of the polystyrene-b-polymethyl methacrylate block copolymer. In some embodiments, the plurality of polymer domains is formed as a result of the guided phase segregation of the polystyrene-b-polymethyl methacrylate block copolymer.

Each of the plurality of polymer domains may comprise at least one of a first region, a second region, a third region, or any combination hereof. In some embodiments, the first region comprises a first polymeric material. In some embodiments, the first region comprises polystyrene chains. In some embodiments, the first region comprises a second polymeric material. In some embodiments, the second region comprises polymethyl methacrylate chains. In some embodiments, the third region is a region located between the first region and the second region. In some embodiments, the third region comprises an intermixed region. In some embodiments, the third region comprises a region in which the first polymeric material and the second polymeric material are not fully segregated. In some embodiments, the third region comprises a region in which the polystyrene chains and the polymethyl methacrylate chains are not fully segregated. In some embodiments, the third region comprises an unsegregated portion of polystyrene chains and polymethyl methacrylate chains.

The substrate may comprise at least one impurity. In some embodiments, the impurity is present in the first region. In some embodiments, the impurity is present in the second region. In some embodiments, the impurity is present in the third region. In some embodiments, the impurity comprises a styrenic impurity. In some embodiments, the impurity comprises a methyl methacrylate impurity. In some embodiments, the impurity comprises at least one of the following: at least one additive, at least one byproduct, at least one residue (e.g., from the third region or intermixing region), or any combination thereof.

At step 204, in some embodiments, the composition is obtained. The composition may comprise any one or more of the compositions disclosed herein without departing from the scope of this disclosure. In some embodiments, for example, the composition comprises a wet etch composition. In some embodiments, the wet etch composition comprises at least one solvent. In some embodiments, the wet etch composition comprises 0.1% to 20% by weight of at least one pH adjuster based on a total weight of the wet etch composition. In some embodiments, the wet etch composition comprises 1% to 20% by weight of at least one oxidizer based on the total weight of the wet etch composition. In some embodiments, when contacted with a non-ultraviolet treated substrate comprising a first polymeric material and a second polymeric material, the composition selectively removes the first polymeric material.

At step 206, in some embodiments, the substrate is contacted with a composition. In some embodiments, the contacting comprises bringing the composition into immediate or close proximity with the substrate. In some embodiments, the contacting comprises bringing the composition into direct physical contact with the substrate. In some embodiments, the contacting comprises coating the composition on the substrate. In some embodiments, the contacting comprises spin-coating the composition onto the substrate. In some embodiments, the contacting comprises casting the composition onto the substrate. In some embodiments, the contacting comprises pouring the composition onto the substrate. In some embodiments, the contacting comprises soaking the substrate in the composition. In some embodiments, the contacting comprises immersing the substrate in the composition. In some embodiments, the contacting comprises placing the substrate in a bath comprising the composition.

In some embodiments, the contacting is performed under conditions sufficient for selective removal of the first polymeric material from the substrate. In some embodiments, the contacting is performed at a temperature of 25° C. to 100° C., or any range or subrange between 25° C. and 100° C. In some embodiments, the contacting is performed at a temperature of 25° C. to 100° C., 25° C. to 90° C., 25° C. to 80° C., 25° C. to 70° C., 25° C. to 60° C., 25° C. to 50° C., 25° C. to 40° C., 25° C. to 30° C., 30° C. to 100° C., 40° C. to 100° C., 50° C. to 100° C., 60° C. to 100° C., 70° C. to 100° C., 80° C. to 100° C., or 90° C. to 100° C. The temperature can be selected to accelerate a removal rate of the first polymeric material and/or to improve critical diameter uniformity of the substrate.

In some embodiments, the contacting is performed for a duration of 1 minute to 24 hours, or any range or subrange between 1 minute and 24 hours. In some embodiments, the contacting is performed for a duration of 1 minute to 24 hours, 1 minute to 20 hours, 1 minute to 15 hours, 1 minute to 10 hours, 1 minute to 9 hours, 1 minute to 8 hours, 1 minute to 7 hours, 1 minute to 6 hours, 1 minute to 5 hours, 1 minute to 4 hours, 1 minute to 3 hours, 1 minute to 2 hours, 1 minute to 1 hour, 1 minute to 60 minutes, 1 minute to 50 minutes, 1 minute to 40 minutes, 1 minute to 30 minutes, 1 minute to 20 minutes, 1 minute to 10 minutes, 1 minute to 5 minutes, 1 hour to 24 hours, 5 hours to 24 hours, 10 hours to 24 hours, 15 hours to 24 hours, or 20 hours to 24 hours.

In some embodiments, the contacting is performed sufficient to obtain an isoporous substrate by removal of at least a portion of the first polymeric material. In some embodiments, the contacting is sufficient to selectively remove the first polymeric material. In some embodiments, the contacting is sufficient to not remove the second polymeric material. The composition may be configured to remove at least a portion of the first polymeric material from the substrate, so as to increase or rectify at least one dimension (e.g., a critical dimension, such as, for example and without limitation, a pore diameter) of at least one of the plurality of polymer domains. In some embodiments, the term “remove” also means to cleave, as defined herein. In some embodiments, the contacting removes at least a portion of the first polymeric material present in at least one of the regions of the plurality of polymer domains. In some embodiments, the contacting removes at least a portion of the first polymeric material present in the second region. In some embodiments, the contacting removes at least a portion of the non-cleaved second polymeric material present in the second region. In some embodiments, the contacting removes at least a portion of the first polymeric material present in the third region. In some embodiments, the contacting removes at least a portion of the non-cleaved second polymeric material present in the third region.

The composition may selectively remove polymethyl methacrylate chains over polystyrene chains sufficient to increase or rectify at least one dimension (e.g., a critical dimension, such as, for example and without limitation, a pore diameter) of at least one of the plurality of polymer domains. In some embodiments, the contacting removes a greater proportion of the polymethyl methacrylate chains present in the second region than the polystyrene chains present in the first region. In some embodiments, the contacting removes a greater proportion of the polymethyl methacrylate chains present in the second region than the polystyrene chains present in the third region. In some embodiments, the contacting removes a greater proportion of the polymethyl methacrylate chains present in the third region than the polystyrene chains present in the third region. In some embodiments, the contacting removes a greater proportion of the polymethyl methacrylate chains present in the third region than the polystyrene chains present in the first region. The composition may be formulated or configured to remove a greater portion of the first polymeric material from the first region than the second polymeric material from the second region.

In some embodiments, the contacting results in forming a porous layer. In some embodiments, the porous layer comprises a plurality of pores. In some embodiments, the porous layer comprises a plurality of nanopores. In some embodiments, the porous layer comprises a plurality of isopores. In some embodiments, the pores of the porous layer have an average pore diameter of 100 nm or less, 90 nm or less, 80 nm or less, 70 nm or less, 60 nm or less, 50 nm or less, 40 nm or less, 30 nm or less, 20 nm or less, 10 nm or less, or 5 nm or less. In some embodiments, the pores of the porous layer have an average pore diameter of 1 nm to 100 nm, or any range or subrange therebetween. For example, the pores of the porous layer may have an average pore diameter of 1 nm to 90 nm, 1 nm to 80 nm, 1 nm to 70 nm, 1 nm to 60 nm, 1 nm to 50 nm, 1 nm to 40 nm, 1 nm to 30 nm, 1 nm to 20 nm, 1 nm to 10 nm, 1 nm to 5 nm, 5 nm to 100 nm, 10 nm to 100 nm, 20 nm to 100 nm, 30 nm to 100 nm, 40 nm to 100 nm, 50 nm to 100 nm, 60 nm to 100 nm, 70 nm to 100 nm, 80 nm to 100 nm, or 90 nm to 100 nm. In some embodiments, the pores of the porous layer have an average pore diameter of 10 nm to 70 nm, 10 nm to 60 nm, 10 nm to 50 nm, 10 nm to 40 nm, 10 nm to 30 nm, 10 nm to 20 nm, 20 nm to 70 nm, 30 nm to 70 nm, 40 nm to 70 nm, 50 nm to 70 nm, 60 nm to 70 nm.

In some embodiments, the contacting results in forming a layer having a surface morphology. For example, in some embodiments, the contacting results in a layer having a patterned surface. The patterned surface may have at least one of lines, spaces, ridges, pillars, valleys, any combination thereof, and the like.

Some embodiments relate to a porous layer or a layer having a surface morphology. In some embodiments, the porous layer comprises any porous layer formed according to any of the methods disclosed herein. In some embodiments, the porous layer is useful as a mask for pattern transfer. In some embodiments, the layer has any of the surface morphologies disclosed herein.

Any one or more of the embodiments disclosed herein shall be understood to be combinable without departing from the scope or spirit of the disclosure.

### EXAMPLES

Several sample compositions were prepared and compared to control compositions. The formulations for each of the compositions is summarized below, with all weight percentages based on a total weight of each composition:

Sample Composition 1
95% by weight of sulfolane;
2% by weight of methane sulfonic acid (70% MSA); and
3% by weight of periodic acid (50% PIA)

Sample Composition 2
84.5% by weight of sulfolane;
10% by weight of gamma butyrolactone;
0.5% by weight of trifluoro acetic acid; and
5% by weight of peroxide (31% H₂O₂).

Control Composition 1
85% by weight of sulfolane;
10% by weight of gamma butyrolactone;
2% by weight of methane sulfonic acid (70% MSA); and
3% by weight of periodic acid (50% PIA)

Control Composition 2
84.5% by weight of sulfolane;
10% by weight of DIW;
0.5% by weight of trifluoro acetic acid; and
5% by weight of peroxide (31% H₂O₂).

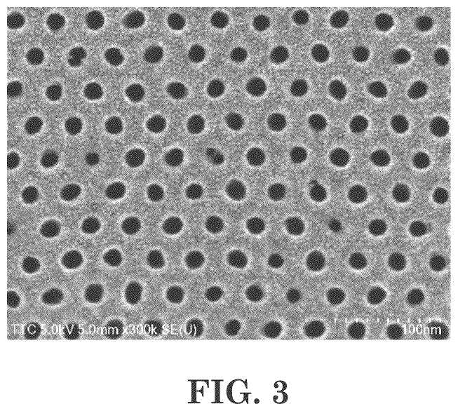

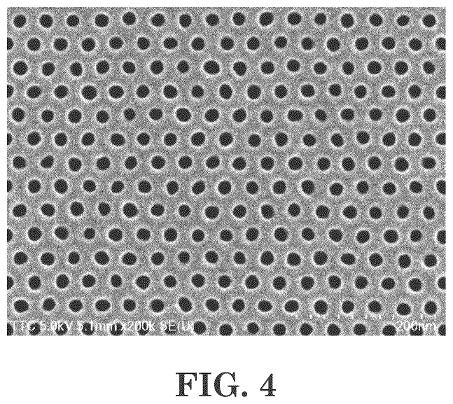

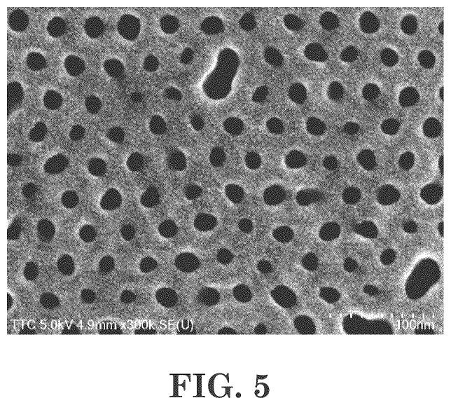

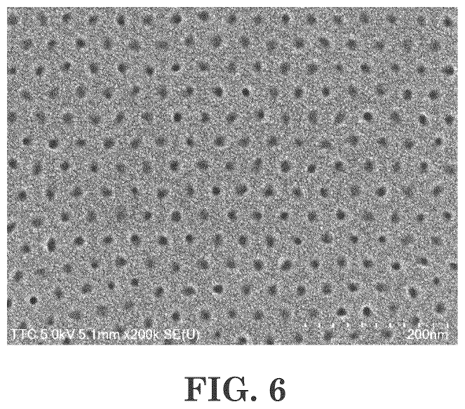

Each of the compositions was used to create a bath. A substrate comprising a phase segregated polystyrene-b-polymethyl methacrylate block copolymer with a plurality of domains (e.g., see FIG. 1) was obtained. For each composition, the substrate was immersed in the bath for a duration of 30 minutes. The temperature at which Sample Composition 1, Sample Composition 2, Control Composition 1, and Control Composition 2 were tested was 45° C. After the substrates were immersed in the bath for the duration identified above, the substrates were removed and rinsed with deionized water. It was observed that Sample Composition 1 and Sample Composition 2 both exhibited well-defined pores formed by removal of the polystyrene (FIG. 3 and FIG. 4, respectively), whereas Control Composition 1 and Control Composition 2 had no well-defined pores or only a limited amount of well-defined pores, with poor pore uniformity (FIG. 5 and FIG. 6, respectively.

### ASPECTS

Various Aspects are described below. It is to be understood that any one or more of the features recited in the following Aspect(s) can be combined with any one or more other Aspect(s).

Aspect 1. A wet etch composition comprising:
at least one solvent;
0.1% to 20% by weight of at least one pH adjuster based on a total weight of the wet etch composition; and
1% to 20% by weight of at least one oxidizer based on the total weight of the wet etch composition;
   wherein, when contacted with a non-ultraviolet treated substrate comprising a first polymeric material and a second polymeric material, the composition selectively removes the first polymeric material.

Aspect 2. The composition according to Aspect 1, wherein the composition comprises:
50% to 98.9% by weight of the at least one solvent based on a total weight of the composition.

Aspect 3. The composition according to any one of Aspects 1-2, wherein the composition comprises:
0.1% to 5% by weight of the at least one pH adjuster based on a total weight of the composition.

Aspect 4. The composition according to any one of Aspects 1-3, wherein the composition comprises:
2% to 8% by weight of the at least one oxidizer based on a total weight of the composition.

Aspect 5. The composition according to any one of Aspects 1-4, wherein the composition further comprises:
0.1% to 10% by weight of an oxidizing agent stabilizer based on the total weight of the composition,
   wherein a remainder of the composition comprises the at least one solvent.

Aspect 6. The composition according to any one of Aspects 1-5, wherein the at least one solvent comprises at least one of a tertiary alcohol, a ketone, an ester, a diester, a carbonate ester, or any combination thereof.

Aspect 7. The composition according to any one of Aspects 1-6, wherein the at least one pH adjuster comprises at least one of an acid, a base, or any combination thereof.

Aspect 8. The composition according to any one of Aspects 1-7, wherein the at least one oxidizer comprises at least one of a metal halide compound, a metal nitrate compound, a metal peroxymonosulfate compound, a metal persulfate compound, a metal perborate compound, a metal permanganate compound, a metal hypochlorite compound, a peroxide compound, a peroxymonosulfate compound, a nitrogen-containing compound, an acid, an ammonium compound, or any combination thereof.

Aspect 9. The composition according to any one of Aspects 1-8, further comprising:
at least one oxidizing agent stabilizer,
   wherein the at least one oxidizing agent stabilizer comprises at least one of a chelating compound, an acid, or any combination thereof.

Aspect 10. The composition according to any one of Aspects 1-9, wherein the composition does not comprise an acetic acid.

Aspect 12. The composition according to any one of Aspects 1-10, wherein the composition does not comprise a swell inhibitor.

Aspect 13. A method comprising:
obtaining a non-ultraviolet treated substrate comprising a first polymeric material and a second polymeric material;
obtaining a composition comprising:
   at least one solvent;
   0.1% to 20% by weight of at least one pH adjuster based on a total weight of the wet etch composition; and
   1% to 20% by weight of at least one oxidizer based on the total weight of the wet etch composition;
contacting the composition with the non-ultraviolet treated substrate to selectively remove the first polymeric material.

Aspect 14. The method according to Aspect 13, wherein the contacting comprises spin-coating the composition onto the non-ultraviolet treated substrate.

Aspect 15. The method according to any one of Aspects 13-14, wherein the contacting comprises immersing the non-ultraviolet treated substrate in the composition.

Aspect 16. The method according to Aspect 15, wherein the immersing is performed at a temperature of 25° C. to 100° C.

Aspect 17. The method according to Aspect 15, wherein the immersing is performed for a duration of 1 minute to 60 minutes.

Aspect 18. The method according to any one of Aspects 13-17, wherein the non-ultraviolet treated substrate is nonporous.

Aspect 19. The method according to Aspect 18, wherein the contacting is sufficient to remove the first polymeric material from the non-ultraviolet treated substrate so as to form an isoporous substrate.

Aspect 20. The method according to any one of Aspects 13-19, wherein the method does not comprise a step of irradiating the substrate with ultraviolet light.

What is claimed is:

1. A composition comprising:
at least one solvent;
0.1% to 20% by weight of at least one pH adjuster based on a total weight of the composition; and
1% to 20% by weight of at least one oxidizer based on the total weight of the composition;
wherein, when contacted with a non-ultraviolet treated substrate comprising a first polymeric material and a second polymeric material, the composition selectively removes the first polymeric material.

2. The composition of claim 1, wherein the composition comprises:
50% to 98.9% by weight of the at least one solvent based on a total weight of the composition.

3. The composition of claim 1, wherein the composition comprises:
0.1% to 5% by weight of the at least one pH adjuster based on a total weight of the composition.

4. The composition of claim 1, wherein the composition comprises:
2% to 8% by weight of the at least one oxidizer based on a total weight of the composition.

5. The composition of claim 1, wherein the composition further comprises:
0.1% to 10% by weight of an oxidizing agent stabilizer based on the total weight of the composition,
wherein a remainder of the composition comprises the at least one solvent.

6. The composition of claim 1, wherein the at least one solvent comprises at least one of a tertiary alcohol, a ketone, an ester, a diester, a carbonate ester, or any combination thereof.

7. The composition of claim 1, wherein the at least one pH adjuster comprises at least one of an acid, a base, or any combination thereof.

8. The composition of claim 1, wherein the at least one oxidizer comprises at least one of a metal halide compound, a metal nitrate compound, a metal peroxymonosulfate compound, a metal persulfate compound, a metal perborate compound, a metal permanganate compound, a metal hypochlorite compound, a peroxide compound, a peroxymonosulfate compound, a nitrogen-containing compound, an acid, an ammonium compound, or any combination thereof.

9. The composition of claim 1, further comprising:
at least one oxidizing agent stabilizer,
wherein the at least one oxidizing agent stabilizer comprises at least one of a chelating compound, an acid, or any combination thereof.

10. The composition of claim 1, wherein the composition does not comprise an acetic acid.

11. The composition of claim 1, wherein the composition does not comprise a swell inhibitor.

12. The composition of claim 1, wherein the composition does not comprise an acetic acid and the composition does not comprise a swell inhibitor.

13. A method comprising:
obtaining a non-ultraviolet treated substrate comprising a first polymeric material and a second polymeric material;
obtaining a composition comprising:
at least one solvent;
0.1% to 20% by weight of at least one pH adjuster based on a total weight of the composition; and
1% to 20% by weight of at least one oxidizer based on the total weight of the composition; and
contacting the composition with the non-ultraviolet treated substrate to selectively remove the first polymeric material.

14. The method of claim 13, wherein the contacting comprises spin-coating the composition onto the non-ultraviolet treated substrate.

15. The method of claim 13, wherein the contacting comprises immersing the non-ultraviolet treated substrate in the composition.

16. The method of claim 15, wherein the immersing is performed at a temperature of 25° C. to 100° C.

17. The method of claim 15, wherein the immersing is performed for a duration of 1 minute to 60 minutes.

18. The method of claim 13, wherein the non-ultraviolet treated substrate is nonporous.

19. The method of claim 18, wherein the contacting is sufficient to remove the first polymeric material from the non-ultraviolet treated substrate so as to form an isoporous substrate.

20. The method of claim 13, wherein the method does not comprise a step of irradiating a substrate with ultraviolet light.
